(19) United States
(12) Patent Application Publication
(10) Pub. No.: US 2025/0271514 A1
(43) Pub. Date: Aug. 28, 2025

(54) TWO-DIMENSIONAL MAGNET-BASED POSITIONING SYSTEM AND METHOD FOR PERFORMING A MAGNET-BASED POSITION DETERMINATION

(71) Applicant: Infineon Technologies AG, Neubiberg (DE)

(72) Inventors: Severin NEUNER, Valley (DE); Stephan LEISENHEIMER, Oberhaching (DE); Jakob VALTL, München (DE); Joo Il PARK, Sungnam-Si (KR); Hyun Jeong KIM, Seoul (KR)

(21) Appl. No.: 19/062,761

(22) Filed: Feb. 25, 2025

(30) Foreign Application Priority Data
Feb. 27, 2024 (DE) 102024201808.2

(51) Int. Cl. G01R 33/02

(52) U.S. Cl. CPC G01R 33/0206

(57) ABSTRACT

Disclosed is a magnet-based positioning system including an axially magnetized magnet, wherein two opposing magnetic poles are arranged along a common z-axis, and a magnetic sensor arrangement being axially spaced apart from the magnet, and being configured to determine magnetic field vectors in an x-y-plane perpendicular to the common z-axis. The magnetic sensor arrangement is configured to determine a first magnetic field vector at a first yet unknown position in the x-y-plane, and to determine a second magnetic field vector at a different second yet unknown position in the x-y-plane, and to determine an actual x-y-position of the magnetic sensor arrangement relative to the magnet based on the first and second magnetic field vectors and based on a known relative spatial distance between the first yet unknown position and the second yet unknown position.

### CROSS-REFERENCE TO RELATED APPLICATION

This application claims priority to Germany Patent Application No. 102024201808.2 filed on Feb. 27, 2024, the content of which is incorporated by reference herein in its entirety.

### FIELD

Implementations of the present disclosure relate to a magnet-based positioning system and to a method for a magnet-based position determination. The innovative concept uses a two-dimensional approach, wherein magnetic field vectors are determined in a two-dimensional x-y-plane.

### BACKGROUND

In some applications it is useful to determine an exact position of a magnet relative to a magnetic sensor. For example, wireless charging of autonomous robots may require that the robots can position themselves towards a wireless charging module at an optimal position in terms of highest charging efficiency. Accordingly, autonomous robots that need to be charged have to know where to go and how to position themselves in the charging stand.

Magnetic solutions are already known, in which the robots comprise a magnetic sensor arrangement for locating a magnet being installed at the charging site. However, these concepts apply a time- and energy-consuming iterative concept, in which a robot has to move step by step closer in the direction of the magnet. Other magnet-based positioning systems require an initial calibration and further regular on-site calibrations, since they may be temperature dependent or dependent on the absolute magnetic field strength.

It would therefore be desirable to improve existing magnet-based positioning systems so that they do not require on-site calibration, enable high-precision positioning and are energy- and cost-efficient.

### SUMMARY

This goal is achieved using the herein disclosed magnet-based positioning system and the corresponding method for performing a magnet-based position determination according to the independent claims. Further implementations and advantageous aspects are suggested in the dependent claims.

The innovative magnet-based positioning system includes an axially magnetized magnet, wherein two opposing magnetic poles are arranged along a common z-axis, and a magnetic sensor arrangement being axially spaced apart from the magnet. The magnetic sensor arrangement is configured to determine magnetic field vectors in an x-y-plane perpendicular to the common z-axis, the magnetic field vectors representing the direction of emanated magnetic field lines in the x-y-plane. The magnetic sensor arrangement is configured to determine a first magnetic field vector at a first yet unknown position (e.g., indicated by first x-y-coordinates (x₁|y₁)) in the x-y-plane, and to determine a second magnetic field vector at a different second yet unknown position (e.g., indicated by second x-y-coordinates (x₂|y₂)) in the x-y-plane. The magnetic sensor arrangement is further configured to determine an actual x-y-position of the magnetic sensor arrangement relative to the magnet based on the first and second magnetic field vectors and based on a known relative spatial distance between the first yet unknown position and the second yet unknown position.

The corresponding innovative method for performing the magnet-based position determination includes a step of providing an axially magnetized magnet, wherein two opposing magnetic poles are arranged along a common z-axis, and a step of providing a magnetic sensor arrangement being axially spaced apart from the magnet, and being configured to determine magnetic field vectors in an x-y-plane perpendicular to the common z-axis, the magnetic field vectors representing the direction of emanated magnetic field lines in the x-y-plane. The method further includes a step of determining a first magnetic field vector at a first yet unknown position (e.g., indicated by first x-y-coordinates (x₁|y₁)) in the x-y-plane, and determining a second magnetic field vector at a different second yet unknown position (e.g., indicated by second x-y-coordinates (x₂|y₂)) in the x-y-plane. The method further includes a step of determining an actual x-y-position of the magnetic sensor arrangement relative to the magnet based on the first and second magnetic field vectors and based on a known relative spatial distance between the first yet unknown position and the second yet unknown position.

Accordingly, even though the two positions are yet unknown to the magnetic sensor arrangement, it may exactly calculate its own position relative to the magnet by only having knowledge about the spatial distance between the two yet unknown positions and by combining both magnetic field vectors with each other in an appropriate way.

According to a further aspect, computer programs are provided, wherein each of the computer programs is configured to implement the above-described method when being executed on a computer or signal processor, so that the above-described method is implemented by one of the computer programs.

### BRIEF DESCRIPTION OF THE DRAWINGS

In the following, implementations of the present disclosure are described in more detail with reference to the figures, in which

FIG. 1A shows a schematic perspective view of commonly known axially magnetized permanent magnet.

FIG. 1B shows a schematic perspective view of commonly known diametrically magnetized permanent magnet.

FIG. 2A shows an implementation of a magnet-based positioning system comprising an axially magnetized magnet and an axially spaced apart x-y sensor plane that is perpendicular to the magnetizing axis of the magnet, where emanating magnetic field lines are schematically depicted.

FIG. 2B shows a schematic representation of magnetic field lines emanated from the magnet, as seen from the x-y sensor plane.

FIG. 3A shows an example of an axially magnetized magnet but with x-z sensor plane that is parallel to the magnetizing axis of the magnet, where emanating magnetic field lines are schematically depicted.

FIG. 3B shows a schematic representation of magnetic field lines emanated from the magnet, as seen from the x-y sensor plane.

FIG. 4 shows a schematic representation of magnetic field lines and magnetic field vectors in the x-y-plane with a magnetic sensor arrangement comprising two magnetic sensor elements according to an implementation.

FIG. 5 shows a further schematic representation of the magnetic field lines and magnetic field vectors of FIG. 4 according to an implementation.

FIG. 6 shows a schematic representation of magnetic field lines and magnetic field vectors in the x-y-plane with a magnetic sensor arrangement comprising one single magnetic sensor element according to an implementation.

FIG. 7 shows a schematic representation of magnetic field lines and magnetic field vectors in the x-y-plane with a magnetic sensor arrangement configured to solve ambiguity problems caused by two identical magnetic field angles according to an implementation, and

FIG. 8 shows a schematic block diagram of an innovative method according to an implementation.

### DETAILED DESCRIPTION

Equal or equivalent elements or elements with equal or equivalent functionality are denoted in the following description by equal or equivalent reference numerals.

Although some aspects will be described in the context of an apparatus, it is clear that these aspects also represent a description of the corresponding method, where a block or device corresponds to a method step or a feature of a method step. Analogously, aspects described in the context of a method step also represent a description of a corresponding block or item or feature of a corresponding apparatus.

Method steps which are depicted using a block diagram and which are described with reference to the block diagram may also be executed in an order different from the depicted and/or described order. Furthermore, method steps concerning a particular feature of a device may be replaceable with the feature of the device, and the other way around.

Furthermore, for ease of understanding of the following description, an x-y-z coordinate system is represented. The depicted z-axis corresponds to the magnetizing axis of the axially magnetized magnet. Accordingly, the terms z-axis and magnetizing axis may be used interchangeably in the following description.

Some applications require an exact position adjustment of two devices relative to each other. For example, in high precision positioning applications, trays or the like need to be precisely positioned in machines for industrial or medical applications. A further field of application covers active motion compensation, where a readjustment due to environmental disturbance in optical applications may be required. Furthermore, fast and accurate adaption in workflow/production may be required, e.g., by readjusting a tool-head in food production or in an assembly lane. Yet further, nearfield navigation may require an exact position adjustment, e.g., autonomous robots navigating into an optimal wireless charging position.

For such positioning tasks, magnetic solutions are known, in which a magnet and a magnetic sensor are provided. Conventional magnetic positioning systems use the magnet's magnetic field strength for adjusting the relative position between the sensor and the magnet, e.g., the higher the field strength the closer the distance between magnet and sensor. However, such magnet-based positioning systems require an initial calibration and further regular on-site calibrations, since they may be temperature dependent or dependent on the absolute magnetic field strength.

The present innovative concept, instead, is independent from the magnetic field strength. It uses an angle calculation of at least two magnetic field vectors. Thus, it is independent from temperature and absolute magnetic field strength rendering it calibration-free. Furthermore, xMR sensors (e.g., TMR, AMR, GMR, etc.) may be used for the present innovative concept which sensors only require low power and which comprise an intrinsic low noise behavior.

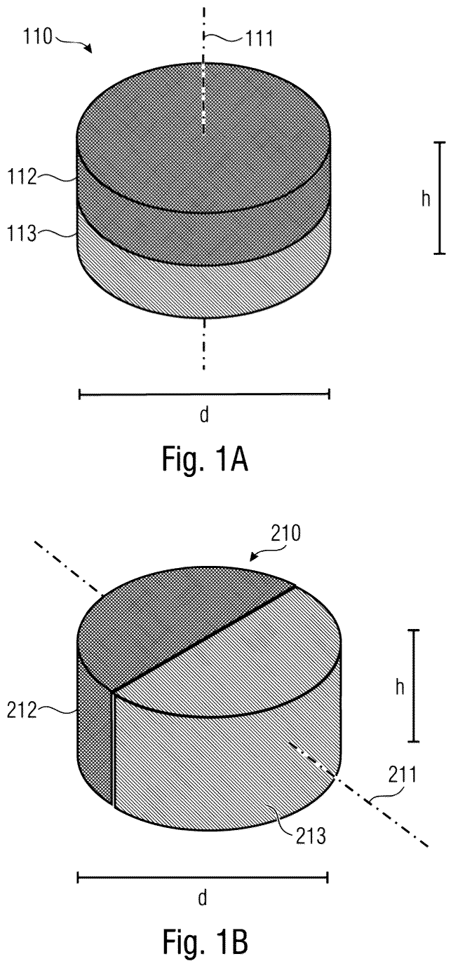

For a brief introduction, FIG. 1A shows an axially magnetized cylinder magnet 110 that is characterized in that its north pole 112 and its south pole 113 are arranged along a vertical axis 111 extending through the magnet 110 along its height h, e.g., perpendicular to its diameter d. In other words, the magnet's north pole 112 and south pole 113 are arranged at the top and bottom of the magnet 110. The vertical axis 111 may also be referred to as a vertical magnetizing axis.

FIG. 1B, in turn, shows a diametrically magnetized cylinder magnet 210 that is characterized in that its north pole 212 and its south pole 213 are arranged along a diametrical axis 211 extending along the diameter d of the magnet 210, e.g., perpendicular to its height h. In other words, the magnet's north pole 212 and south pole 213 are arranged at the left and right side of the magnet 210. The diametrical axis 211 may also be referred to as a diametrical magnetizing axis.

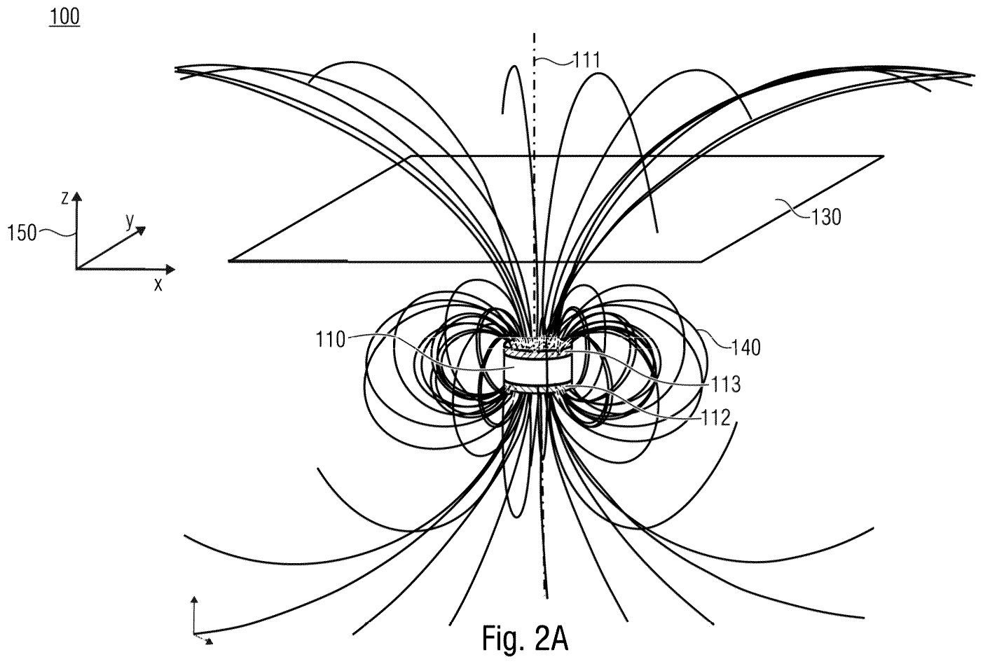

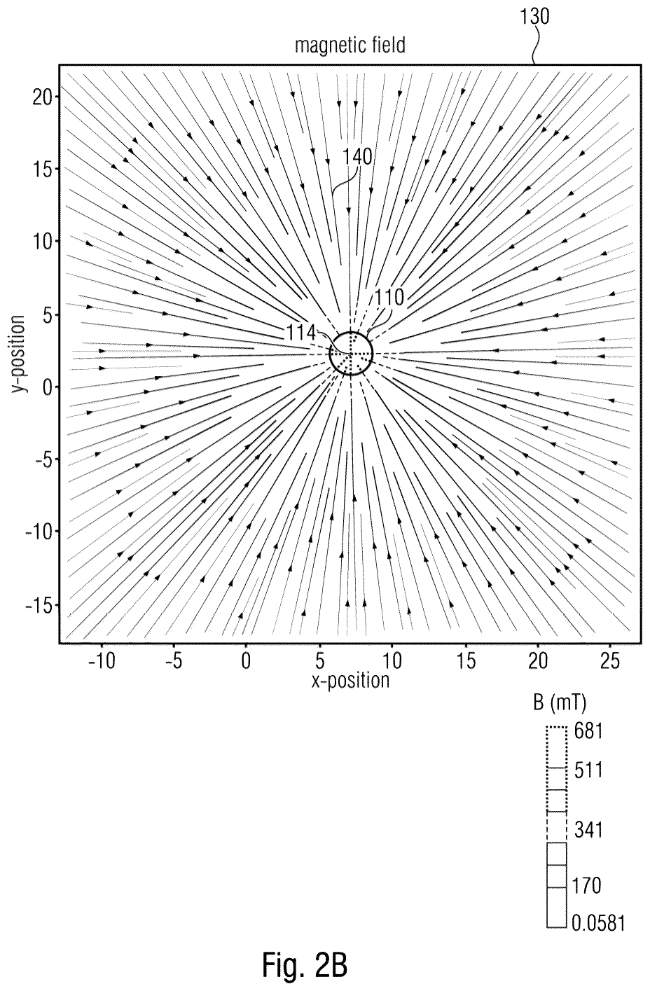

FIG. 2A shows an implementation of an innovative magnet-based positioning system 100. It comprises an axially magnetized magnet 110. The axially magnetized magnet 110 may comprise a symmetrical cylinder or ring shape, though other geometrical shapes are also possible. Two opposing magnetic poles 112, 113 of the magnet 110 are arranged along a common z-axis 111, which corresponds to the above described magnetizing axis of the magnet 110. A coordinate system 150 that is schematically depicted in FIG. 2A shows the orientation of the z-axis 110. In this example, the z-axis 111 extends vertically through the magnet 110 along its height h (c.f. FIG. 1A).

As can be seen, a plurality of magnetic field lines 140 emanate from the magnet 110 in a way as is known in this field of technology. As can further be seen, an x-y-plane 130 is depicted in FIG. 2A, the x-y-plane being spanned such that it extends perpendicular to the aforementioned z-axis 111 (magnetizing axis). In particular, each one of an x-axis and a y-axis of the x-y-plane 130 is perpendicular to the z-axis 111 (magnetizing axis). Accordingly, the x-y-plane 130 is perpendicular to the magnetizing axis 111 of the magnet 110.

The x-y-plane 130 is axially, e.g., along the z-axis 111 (magnetizing axis) spaced apart from the magnet 110. In this non-limiting example, the x-y-plane 130 is located above the magnet 110. However, it may also be possible that the x-y-plane 130 would be located below the magnet 110.

The x-y-plane 130 represents a sensor plane, e.g., a plane in which an innovative magnetic sensor arrangement (not depicted here) is arranged. Accordingly, the innovative magnet-based positioning system 100 comprises a magnetic sensor arrangement that is axially spaced apart from the magnet 110. One can say, the magnet 110 and the magnetic sensor arrangement are arranged in two different spaced apart x-y-planes.

As will be described further below, some implementations may provide for a magnetic sensor arrangement comprising one single magnetic sensor element, or exactly two magnetic sensor elements, or exactly three magnetic sensor elements. More than three magnetic sensor elements may also be possible.

The innovative magnetic sensor arrangement is configured to determine magnetic field vectors in the x-y-plane 130, the magnetic field vectors representing the direction of the emanated magnetic field lines 140 in the x-y-plane 130. The magnetic field lines 140 themselves comprise a magnitude and a direction. Thus, they may also be referred to as magnetic field vectors, and the magnetic field may be referred to as a magnetic vector field. The innovative magnetic sensor arrangement may be configured to measure the direction, and optionally also the magnitude, of the magnetic field vectors 140.

FIG. 2B shows a top view from the x-y-plane 130 onto the magnet 110. Since the x-y-plane 130 is perfectly orthogonal to the z-axis 111, the magnetic field vectors 140 are perfectly symmetrical, namely perfectly radial with respect to the center 114 of the magnet 110. In other words, the magnetic field vectors 140 of the axially magnetized magnet 110 always point towards, or away from, the center 114 of the magnet 110. This is also what the magnetic sensor arrangement sees. One big advantage of this constellation is the fact that the symmetry of the magnetic field vectors 140 does not depend on the magnetic field strength, e.g., the magnetic sensor arrangement always sees the same radial pattern of the magnetic field vectors 140 irrespective of the magnetic field strength of the magnet 110.

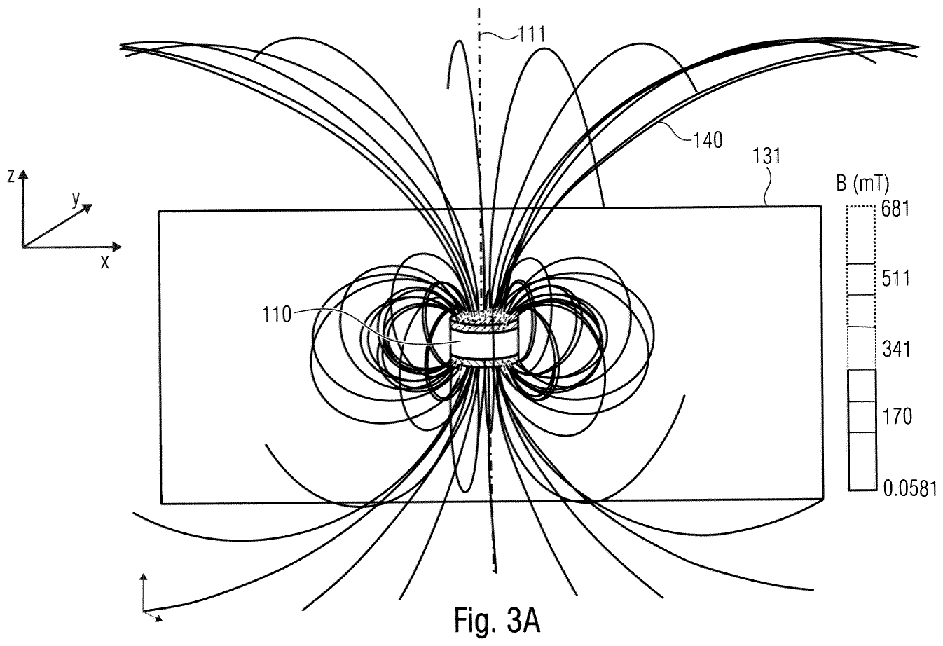

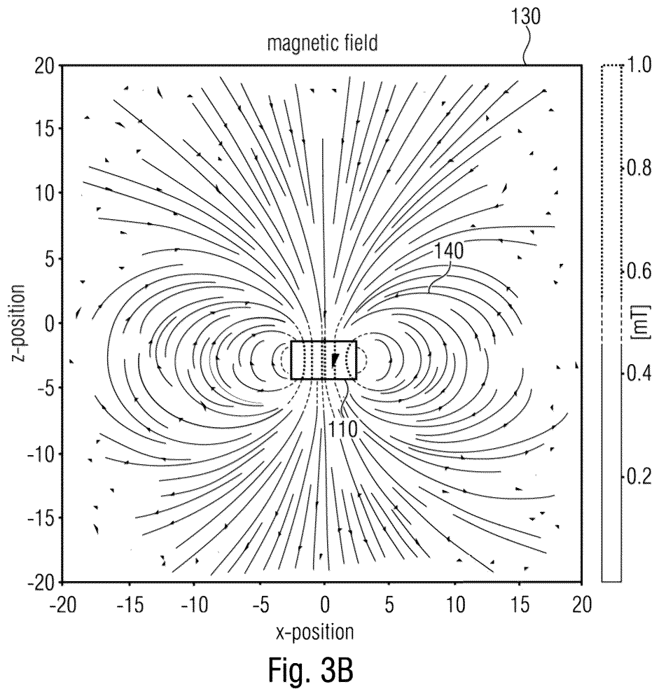

FIGS. 3A and 3B, in turn, show a scenario in which a sensor arrangement is arranged in an x-z-plane 131. In contrast to FIGS. 2A and 2B, the x-z-plane 130 is not perpendicular but parallel to the magnetizing axis 111 of the magnet 110. The same holds for a (not depicted y-z-plane.

In case of such parallel planes, the magnetic field vectors 140 are not perfectly radial, but they are curved instead, wherein the curves point towards the magnet 110 or away from it. The same holds for a y-z-plane. The curvy pattern of the magnetic field vectors 140 highly depends on the magnetic field strength. Without calibration it is nearly impossible to exactly determine the position of the magnet 110 using a magnetic sensor being arranged in a plane 131 being oriented parallel to the magnet axis 111 of the magnet 110.

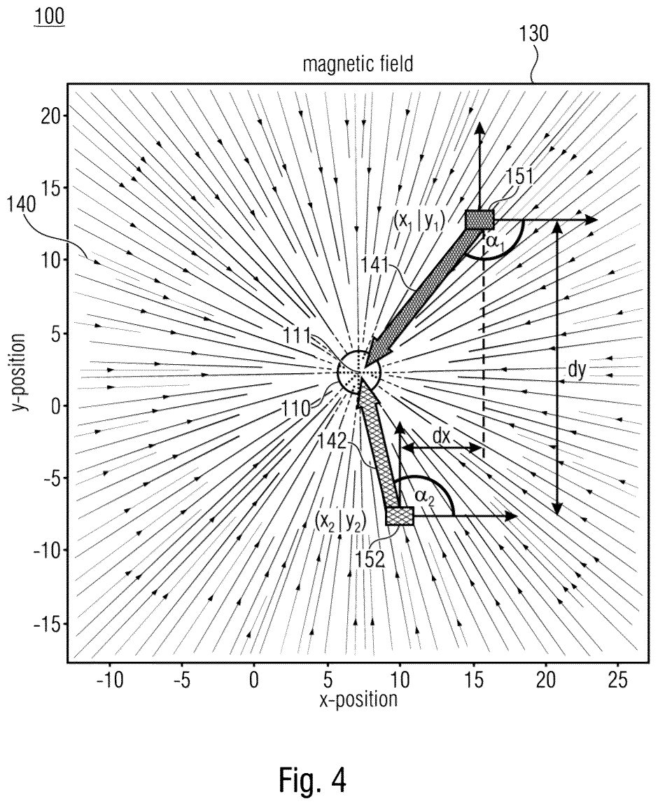

FIG. 4 shows a view from the x-y-plane 130 as previously discussed with reference to FIGS. 2A and 2B. As an example, an autonomous robot may be equipped with the magnetic sensor arrangement, while a charging site may be equipped with the magnet 110, or the other way around. The depicted x-y-plane 130, in which the magnetic sensor arrangement is arranged, is perpendicular to the magnet axis 111 of the axially magnetized magnet 110. Accordingly, the magnetic sensor arrangement being provided on the robot sees the magnetic field vectors 140 as exemplarily depicted in FIG. 4. With the herein discussed innovative concept, the robot may precisely determine its position and/or orientation and/or location relative to the magnet 110 provided at the charging site. Thus, the robot may drive to an optimal charging position relative to the magnet 110.

In the implementation shown in FIG. 4, the sensor arrangement may comprise a first magnetic sensor element 151 and a second magnetic sensor element 152. The first magnetic sensor element 151 is located at a first yet unknown position, which is exemplarily indicated with a first x-y-coordinate (x₁|y₁) in the x-y-plane 130. The second magnetic sensor element 152 is located at a different second yet unknown position, which is exemplarily indicated with a second x-y-coordinate (x₂|y₂) in the x-y-plane 130. The positions (x₁|y₁) and (x₂|y₂) of the magnetic sensor elements 151, 152 are unknown with respect to the position of the magnet 110, e.g., the relative position between the magnetic sensor arrangement and the magnet 110 are yet unknown.

The first and second magnetic sensor elements 151, 152 are spaced apart from each other, wherein a spatial distance (dx|dy) between the first and second magnetic sensor elements 151, 152 is known to the magnetic sensor arrangement. Accordingly, the spatial distance between the first magnetic sensor element 151 and the second magnetic sensor element 152 defines a known relative distance (dx|dy) between the first yet unknown position (x₁|y₁) and the second yet unknown position (x₂|y₂).

The magnetic sensor arrangement is configured to determine a first magnetic field vector 141 at the first yet unknown position (x₁|y₁) in the x-y-plane 130, e.g., using the first magnetic sensor element 151. The magnetic sensor arrangement is further configured to determine a second magnetic field vector 142 at the different second yet unknown position (x₂|y₂) in the x-y-plane 130, e.g., using the second magnetic sensor element 152. Other implementations with only one single magnetic sensor element, or with three different magnetic sensor elements will be discussed further below.

According to the innovative concept, the magnetic sensor arrangement is configured to determine an actual x-y-position of the magnetic sensor arrangement relative to the magnet 110 based on the aforementioned first and second magnetic field vectors 141, 142 and based on the aforementioned known relative spatial distance (dx|dy) between the first yet unknown position (x₁|y₁) and the second yet unknown position (x₂|y₂).

For example, the magnetic sensor arrangement may be configured to determine its actual x-y-position based on a two-dimensional triangulation using the first and second magnetic field vectors 141, 142. The triangulation may be performed with using the aforementioned known relative spatial distance (dx|dy) between the first yet unknown position (x₁|y₁) and the second yet unknown position (x₂|y₂) in combination with two angles.

As can be seen in FIG. 4, due to the above discussed perfect symmetry of the magnetic field lines 140, each magnetic field vector 141, 142 may comprise an unambiguous magnetic field angle α₁, α₂. The first magnetic field angle α₁ describes an angle of the first magnetic field vector 141 extending between the first yet unknown position (x₁|y₁) and the common z-axis 111. The second magnetic field angle α₂ describes an angle of the second magnetic field vector 142 extending between the second yet unknown position (x₂|y₂) and the common z-axis 111.

Since each magnetic field angle α always points towards the center of the magnet 110, which is represented by the common z-axis 111, any magnetic field angle α may be calculated by the following equation:

$$α = atan 2 ( \frac{y}{x} ) \qquad [ eq . 1 ]$$

However, a distance information, e.g., a distance between the magnetic sensor arrangement and the magnet 110, may still be missing. However, this can be solved by a measurement at multiple positions. In other words, by measuring the magnetic field angle α in the x-y-plane 130 at two or more locations, the exact position of the magnet 110 relative to the sensor arrangement can be calculated by using triangulation, as will be described in the following.

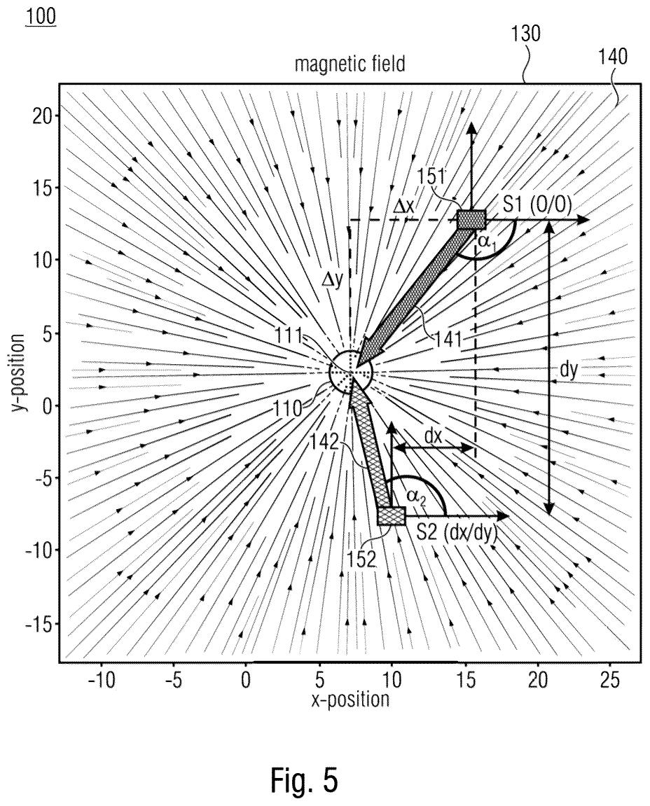

FIG. 5 shows an implementation of an innovative magnet-based position determination system 100 for calculating the missing distance information, e.g., the missing spatial distance between the magnetic sensor arrangement and the magnet 110, wherein the missing distance information is exemplarily indicated by Δx and Δy. As mentioned above, the first position (x₁|y₁) and the second position (x₂|y₂) are both yet unknown. Only the relative distance (dx|dy) between the first yet unknown position (x₁|y₁) and the second yet unknown position (x₂|y₂) is known to the magnetic sensor arrangement.

Optionally, the first yet unknown position (x₁|y₁) may be set as a zero point (0|0) in the x-y-plane 130. Then, the second yet unknown position (x₂|y₂) may be defined as (dx|dy), which indicate the known relative distance (dx|dy) between the first yet unknown position (x₁|y₁) and the second yet unknown position (x₂|y₂).

The missing distance information, e.g., the yet unknown spatial distance between the magnetic sensor arrangement and the magnet 110 may now be calculated by calculating a spatial distance Δx, Δy between the first magnetic sensor arrangement 151 and the common z-axis 111 (=magnetizing axis), as exemplarily depicted in FIG. 5, and/or by calculating a spatial distance between the second magnetic sensor arrangement 152 and the common z-axis 111 (=magnetizing axis). As mentioned above, alternative implementations with only one single magnetic sensor element, or with three different magnetic sensor elements will be discussed further below.

Accordingly, while the spatial distance between the first magnetic sensor arrangement 151 and the common z-axis 111 (=magnetizing axis) may be defined as Δx, Δy, the spatial distance between the second magnetic sensor arrangement 152 and the common z-axis 111 (=magnetizing axis) may be defined as Δx+dx, Δy+dy.

These coordinates may now be inserted into above equation 1, where α₁ defines the first magnetic field angle belonging to the first magnetic field vector 141, and α₂ defines the second magnetic field angle belonging to the second magnetic field vector 142:

$$tan ( {α}_{1} ) = \frac{Δ x}{Δ y} \qquad [ eq . 2 ]$$

$$tan ( {α}_{2} ) = \frac{Δ x + dx}{Δ y + dy} \qquad [ eq . 3 ]$$

As can be seen, the above equations have two unknowns, namely Δx and Δy. Thus, equations 2 and 3 may be solved for Δx and Δy through substitution according to the following equations:

$$Δ x = Δ y \cdot tan ( {α}_{1} ) \qquad [ eq . 4 ]$$

$$tan ( {α}_{2} ) = \frac{Δ y \cdot tan ( {α}_{1} ) + dx}{Δ y + dy} \qquad [ eq . 5 ]$$

$$Δ y \cdot tan ( {α}_{2} ) + dy \cdot tan ( {α}_{2} ) = Δ y \cdot tan ( {α}_{1} ) + dx \qquad [ eq . 6 ]$$

$$Δ y \cdot ( tan ( {α}_{2} ) - tan ( {α}_{1} ) ) = dx - dy \cdot tan ( {α}_{2} ) \qquad [ eq . 7 ]$$

$$Δ y = \frac{dx - dy \cdot tan ( {α}_{2} )}{tan ( {α}_{2} ) - tan ( {α}_{1} )} \qquad [ eq . 8 ]$$

$$Δ x = Δ y \cdot tan ( {α}_{1} ) \qquad [ eq . 9 ]$$

Accordingly, the magnetic sensor arrangement may determine its actual x-y-position relative to the magnet 110 by calculating the spatial distance Δx, Δy between at least one of the first and second yet unknown positions (x₁|y₁), (x₂|y₂) and the common z-axis 111 (=magnetizing axis) based on the first and second magnetic field angles α₁, α₂ and based on the known relative distance (dx|dy) between the first yet unknown position (x₁|y₁) and the second yet unknown position (x₂|y₂).

The above equations can, however, only be solved when tan (α₂)≠tan (α₁). That means physically that the first magnetic sensor element 151 and the second magnetic sensor element 152 are not allowed to be in one common line with the magnet 110. In other words, the first magnetic sensor element 151 and the second magnetic sensor element 152 shall not lie on the same magnetic field line 140.

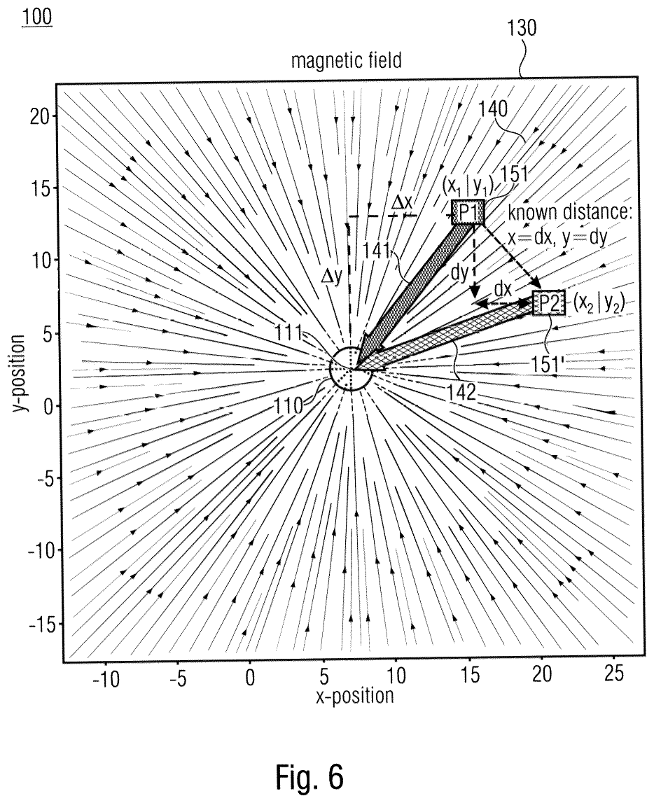

FIG. 6 shows an alternative implementation, in which only one single sensor element 151 is used for determining the actual x-y-position of the magnetic sensor arrangement relative to the magnet 110.

In this implementation, the magnet-based positioning system 100 may move the single magnetic sensor element 151 from the first yet unknown position (x₁|y₁) to the second yet unknown position (x₂|y₂) along a predetermined moving distance x=dx, y=dy. The predetermined moving distance x=dx, y=dy defines the aforementioned known relative distance (dx|dy) between the first yet unknown position (x₁|y₁) and the second yet unknown position (x₂|y₂).

As schematically depicted in FIG. 6, the single magnetic sensor element being located at the first yet unknown position (x₁|y₁) is referenced with reference numeral 151, while the single magnetic sensor element being located at the second yet unknown position (x₂|y₂) is exemplarily referenced with reference numeral 151′.

According to the innovative concept, the magnetic sensor arrangement may determine the first magnetic field angle α₁ when the single magnetic sensor element 151 is located at the first yet unknown position (x₁|y₁) according to the following equation:

$${α}_{1} = atan 2 ( \frac{y}{x} ) \qquad [ eq . 10 ]$$

After moving the single magnetic sensor element 151 from the first yet unknown position (x₁|y₁) to the second yet unknown position (x₂|y₂), the magnetic sensor arrangement may determine the second magnetic field angle α₂ according to the following equation:

$${α}_{2} = atan 2 ( \frac{y}{x} ) \qquad [ eq . 11 ]$$

When moving the single magnetic sensor element 151 from the first yet unknown position (x₁|y₁) to the second yet unknown position (x₂|y₂) by the known distance (dx|dy), the single magnetic sensor element 151 should not be moved into a direction (forwards/backwards) along the current magnetic field line 140, because then the magnetic field angles α₁, α₂ would be identical. In other words, the magnet-based positioning system 100 may move the single magnetic sensor element 151 in a direction different to the first magnetic field angle α₁ (forwards along magnetic field line 140) and different to the first magnetic field angle α₁ plus/minus 180° (backwards along magnetic field line 140).

For example, the magnet-based positioning system 100 may move the single magnetic sensor element 151 in a direction perpendicular to the first magnetic field angle α₁, such as exemplarily depicted in FIG. 6.

After having calculated the first magnetic field angle α₁ for the first magnetic field vector 141 according to equation 10 and the second magnetic field angle α₂ for the second magnetic field vector 142 according to equation 11, the missing distance information Δx, Δy may be calculated in the same way as in the implementation above (FIG. 4) according to equations 2 to 7 leading to the same following results as above:

$$Δ y = \frac{dx - dy \cdot tan ( {α}_{2} )}{tan ( {α}_{2} ) - tan ( {α}_{1} )}$$

$$Δ x = Δ y \cdot tan ( {α}_{1} )$$

As mentioned above, the single magnetic sensor element 151 should not be moved into a direction (forwards/backwards) along the current magnetic field line 140 otherwise the first and second magnetic field angles α₁, α₂ would be identical leading to the consequence that the above equations cannot be solved. The same problem may occur if, in case of the above implementation with two magnetic sensor elements 151, 152 (FIG. 4), both magnetic sensor elements 151, 152 would be located on the same magnetic field line 140.

In order to solve such ambiguity problems, the two magnetic sensor elements 151, 152 (FIG. 4), or the single magnetic sensor element 151 (FIG. 6) may be moved to a third yet unknown position (x₃|y₃) and the above calculations may be repeated with using the third yet unknown position (x₃|y₃) instead of either one of the first and second yet unknown positions (x₁|y₁) and (x₂|y₂).

Accordingly, if the magnetic sensor arrangement may determine that the first magnetic field angle α₁ and the second magnetic field angle α₂ are identical (or are shifted by ±180°), then the magnet-based positioning system 100 may move the magnetic sensor arrangement (having one single sensor element 151 or two sensor elements 151, 152) relative to the magnet 110 and may determine a new second magnetic field angle α₂ at a third yet unknown position (x₃|y₃).

Of course, also in this case, it may be advantageous to move the magnetic sensor arrangement into a direction different to the first or second magnetic field angles α₁, α₂ (forwards along magnetic field line 140) and different to the first or second magnetic field angles α₁, α₂±180° (backwards along magnetic field line 140).

Again, it may be advantageous to move the magnetic sensor arrangement (having one single sensor element 151 or two sensor elements 151, 152) in a direction perpendicular to the first or second magnetic field angles α₁, α₂.

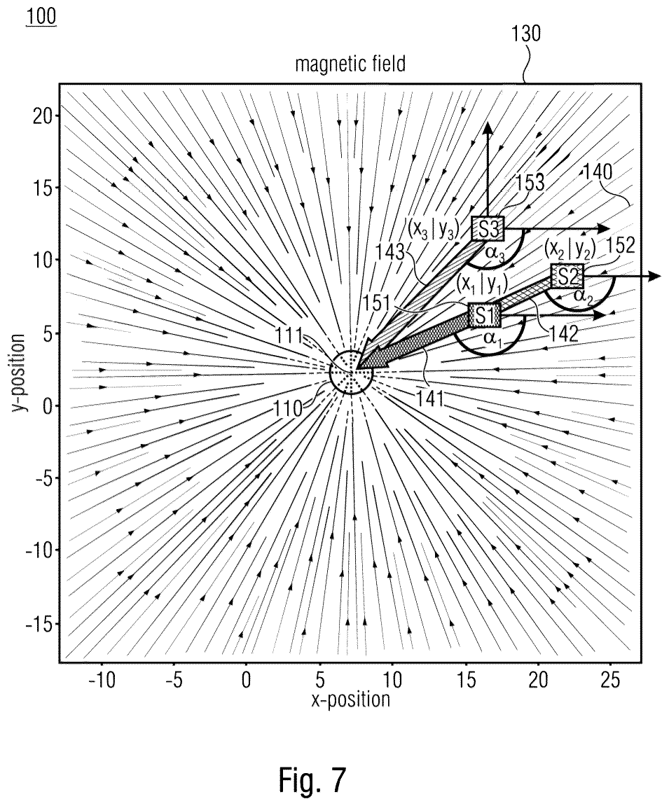

FIG. 7 shows a further implementation for solving such ambiguity problems. In this implementation, the magnet-based positioning system 100 may further comprise a third magnetic sensor element 153 located at a third yet unknown position (x₃|y₃).

The third magnetic sensor element 153 may be placed on a different axis than the first and second magnetic sensor elements 151, 152, such that all three magnetic sensor elements 151, 152, 153 may comprise the shape of a triangle. Thus, further ambiguities can be avoided.

The magnetic sensor arrangement having three magnetic sensor elements 151, 152, 153 may be configured to determine a third magnetic field vector 143 at the third yet unknown position (x₃|y₃) in the x-y-plane 130. The magnetic sensor arrangement may also be configured to determine a third magnetic field angle α₃ that describes the angle of the third magnetic field vector 143 extending between the third yet unknown position (x₃|y₃) and the common z-axis 111 (=magnetizing axis).

So, if the magnetic sensor arrangement determines that the first and second magnetic sensor elements 151, 152 are arranged along a common magnetic field line 140, e.g., if the first magnetic field angle α₁ and the second magnetic field angle α₂ are identical (or are shifted by ±180°), then the magnetic sensor arrangement may use the determined third magnetic field angle α₃ instead of one of the first and second magnetic field angles α₁, α₂ and to use the determined third magnetic field vector 143 instead of one of the first and second magnetic field vectors 141,142. In this case, the determination of the actual x-y-position of the magnetic sensor arrangement relative to the magnet 110 is based on a combination of either one of the first and second magnetic field vectors 141, 142 and third magnetic field vector 143.

Summarizing, the innovative concept suggests three possible solutions for solving he above discussed ambiguities caused by identical first and second magnetic field angles α₁, α₂.

For a first possible solution, use a third magnetic sensor element 153 and place it in a different axis than the first and second magnetic sensor elements 151, 152 such that all three magnetic sensor elements 151, 152, 153 form a triangle:

With an innovative magnetic sensor arrangement having three magnetic sensor elements 151, 152, 153, it is always possible to instantly determine the relative position between the magnetic sensor arrangement and the magnet 110 in the herein described innovative way. However, the usage of three magnetic sensor elements 151, 152, 153 may be more expensive than the above discussed implementations having only two magnetic sensor elements 151, 152 or even only one single magnetic sensor element 151.

For a second possible solution, use two magnetic sensor elements 151, 152 and move at least one of the first and second magnetic sensor elements 151, 152 out of the common magnetic field line 140:

For positioning purposes either the magnet 110 or the magnetic sensor arrangement may be movable. Thus, if the first and second magnetic field angles α₁, α₂ measured by the first and second magnetic sensor elements 151, 152 are equal, a movement can be initiated in order to determine the relative position between the magnet 110 and the magnetic sensor arrangement. An exact position calculation is possible with only two magnetic sensor elements 151, 152, but not always instantly.

For a third possible solution, use only one single magnetic sensor element 151 and sequentially move it to different positions:

According to this implementation, the single sensor element 151 may determine a first magnetic field angle α₁ at a first position (x₁|y₁), then the sensor element 151 may be moved, e.g., perpendicular to the first magnetic field vector 141, to a second position (x₂|y₂), where a second magnetic field angle α₂ may be determined. In order to avoid further ambiguities, the single sensor element 151 shall not be moved in the direction of (or away from) the first magnetic field angle α₁.

This implementation may use only one single sensor element 151 and one magnet 110, wherein the relative position between the magnetic sensor arrangement and the magnet 110 is not known instantly but it is always known after two measurements (with the movement in between) of the two magnetic field angles α₁, α₂. Furthermore, the moved distance needs to be known.

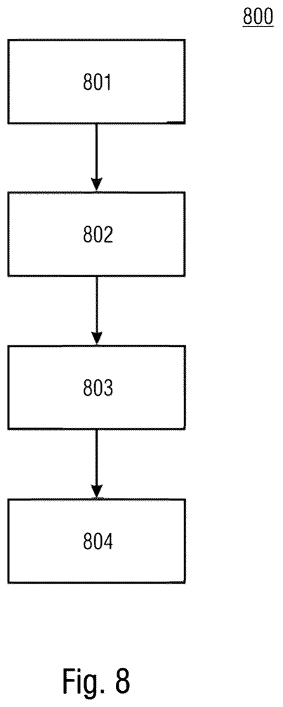

FIG. 8 shows a schematic block diagram of a corresponding method for performing a magnet-based position determination according to the above discussed innovative concept.

In block 801, an axially magnetized magnet 110 is provided, wherein two opposing magnetic poles 112, 113 are arranged along a common z-axis 111.

In block 802, a magnetic sensor arrangement is provided, the magnetic sensor arrangement being axially spaced apart from the magnet 110 and being configured to determine magnetic field vectors 141, 142 in an x-y-plane 130 perpendicular to the common z-axis 111. The magnetic field vectors 141, 142 represent a direction of emanated magnetic field lines 140 in the x-y-plane 130.

In block 803, a first magnetic field vector 141 is determined at a first yet unknown position (x₁|y₁) in the x-y-plane 130, and a second magnetic field vector 142 is determined at a different second yet unknown position (x₂|y₂) in the x-y-plane 130.

In block 804, an actual x-y-position of the magnetic sensor arrangement relative to the magnet 110 is determined based on the first and second magnetic field vectors 141, 142 and based on a known relative spatial distance (dx|dy) between the first yet unknown position (x₁|y₁) and the second yet unknown position (x₂|y₂).

A further implementation concerns a computer-readable storage medium having a computer program stored thereon, for performing, when being executed on a computer or signal processor, the herein described method.

A further implementation concerns a non-transitory computer-readable storage medium having a computer program, stored thereon, for causing a computer or a signal processor to execute a method for performing a magnet-based position determination using an axially magnetized magnet having two opposing magnetic poles arranged along a common z-axis, and using a magnetic sensor arrangement being axially spaced apart from the axially magnetized magnet, and being configured to determine magnetic field vectors in an x-y-plane perpendicular to the common z-axis, the magnetic field vectors representing directions of emanated magnetic field lines in the x-y-plane.

Some or all of the method steps may be executed by (or using) a hardware apparatus, like for example, a microprocessor, a programmable computer or an electronic circuit. In some implementations, one or more of the most important method steps may be executed by such an apparatus.

Depending on certain implementation requirements, implementations can be implemented in hardware or in software or at least partially in hardware or at least partially in software. The implementation can be performed using a digital storage medium, for example a floppy disk, a DVD, a Blu-Ray, a CD, a ROM, a PROM, an EPROM, an EEPROM or a FLASH memory, having electronically readable control signals stored thereon, which cooperate (or are capable of cooperating) with a programmable computer system such that the respective method is performed. Therefore, the digital storage medium may be computer readable.

Some implementations comprise a data carrier having electronically readable control signals, which are capable of cooperating with a programmable computer system, such that one of the methods described herein is performed.

Generally, implementations can be implemented as a computer program product with a program code, the program code being operative for performing one of the methods when the computer program product runs on a computer. The program code may for example be stored on a machine readable carrier.

Other implementations comprise the computer program for performing one of the methods described herein, stored on a machine readable carrier.

In other words, an implementation of the inventive method is, therefore, a computer program having a program code for performing one of the methods described herein, when the computer program runs on a computer.

A further implementation of the inventive methods is, therefore, a data carrier (or a digital storage medium, or a computer-readable medium) comprising, recorded thereon, the computer program for performing one of the methods described herein. The data carrier, the digital storage medium or the recorded medium are typically tangible and/or non-transitory.

A further implementation of the inventive method is, therefore, a data stream or a sequence of signals representing the computer program for performing one of the methods described herein. The data stream or the sequence of signals may for example be configured to be transferred via a data communication connection, for example via the Internet.

A further implementation comprises a processing means, for example a computer, or a programmable logic device, configured to or adapted to perform one of the methods described herein.

A further implementation comprises a computer having installed thereon the computer program for performing one of the methods described herein.

A further implementation comprises an apparatus or a system configured to transfer (for example, electronically or optically) a computer program for performing one of the methods described herein to a receiver. The receiver may, for example, be a computer, a mobile device, a memory device or the like. The apparatus or system may, for example, comprise a file server for transferring the computer program to the receiver.

In some implementations, a programmable logic device (for example a field programmable gate array) may be used to perform some or all of the functionalities of the methods described herein. In some implementations, a field programmable gate array may cooperate with a microprocessor in order to perform one of the methods described herein. Generally, the methods are preferably performed by any hardware apparatus.

The apparatus described herein may be implemented using a hardware apparatus, or using a computer, or using a combination of a hardware apparatus and a computer.

The methods described herein may be performed using a hardware apparatus, or using a computer, or using a combination of a hardware apparatus and a computer.

While this disclosure has been described with reference to illustrative implementations, this description is not intended to be construed in a limiting sense. Various modifications and combinations of the illustrative implementations, as well as other implementations of this disclosure, will be apparent to persons skilled in the art upon reference to the description. It is therefore intended that the appended claims encompass any such modifications or implementations.

### Aspects

The following provides an overview of some Aspects of the present disclosure:

Aspect 1: A magnet-based positioning system, comprising: an axially magnetized magnet, wherein two opposing magnetic poles of the axially magnetized magnet are arranged along a common z-axis; and a magnetic sensor arrangement being axially spaced apart from the axially magnetized magnet, and being configured to determine magnetic field vectors in an x-y-plane perpendicular to the common z-axis, the magnetic field vectors representing directions of emanated magnetic field lines in the x-y-plane, wherein the magnetic sensor arrangement is configured to determine a first magnetic field vector at a first yet unknown position in the x-y-plane, and to determine a second magnetic field vector at a different second yet unknown position in the x-y-plane, and to determine an actual x-y-position of the magnetic sensor arrangement relative to the axially magnetized magnet based on the first magnetic field vector and the second magnetic field vector and based on a known relative spatial distance between the first yet unknown position and the second yet unknown position.

Aspect 2: The magnet-based positioning system according to Aspect 1, wherein the magnetic sensor arrangement is configured to determine the actual x-y-position based on a triangulation using the first magnetic field vector and the second magnetic field vector.

Aspect 3: The magnet-based positioning system according to any of Aspects 1-2, wherein the magnetic sensor arrangement is configured to: determine a first magnetic field angle that describes an angle of the first magnetic field vector extending between the first yet unknown position and the common z-axis, and determine a second magnetic field angle that describes an angle of the second magnetic field vector extending between the second yet unknown position and the common z-axis.

Aspect 4: The magnet-based positioning system according to Aspect 3, wherein the known relative spatial distance between the first yet unknown position and the second yet unknown position is known to the magnetic sensor arrangement, and wherein the magnetic sensor arrangement is configured to determine the actual x-y-position relative to the axially magnetized magnet by calculating a spatial distance between at least one of the first yet unknown position or the second yet unknown position and the common z-axis based on the first magnetic field angle and the second magnetic field angle and based on the known relative spatial distance between the first yet unknown position and the second yet unknown position.

Aspect 5: The magnet-based positioning system according to Aspect 4, wherein the magnetic sensor arrangement comprises a first magnetic sensor element located at the first yet unknown position and a second magnetic sensor element located at the second yet unknown position, and wherein a spatial distance between the first magnetic sensor element and the second magnetic sensor element defines the known relative spatial distance between the first yet unknown position and the second yet unknown position.

Aspect 6: The magnet-based positioning system according to Aspect 4, wherein the magnetic sensor arrangement comprises a single magnetic sensor element, wherein the magnet-based positioning system is configured to move the single magnetic sensor element from the first yet unknown position to the second yet unknown position along a predetermined moving distance, wherein the predetermined moving distance defines the known relative spatial distance between the first yet unknown position and the second yet unknown position, and wherein the magnetic sensor arrangement is configured to: determine the first magnetic field angle when the single magnetic sensor element is located at the first yet unknown position, and determine the second magnetic field angle when the single magnetic sensor element is located at the second yet unknown position.

Aspect 7: The magnet-based positioning system according to Aspect 6, wherein, after determining the first magnetic field angle, the magnet-based positioning system is configured to move the single magnetic sensor element in a direction different to the first magnetic field angle and different to the first magnetic field angle ±180°.

Aspect 8: The magnet-based positioning system according to Aspect 6, wherein, after determining the first magnetic field angle, the magnet-based positioning system is configured to move the single magnetic sensor element in a direction perpendicular to the first magnetic field angle.

Aspect 9: The magnet-based positioning system according to Aspect 3, wherein, if the magnetic sensor arrangement determines that the first magnetic field angle and the second magnetic field angle are identical, or are shifted by ±180°, the magnet-based positioning system is configured to move the magnetic sensor arrangement relative to the axially magnetized magnet and to determine the second magnetic field angle at a third yet unknown position.

Aspect 10: The magnet-based positioning system according to Aspect 9, the magnet-based positioning system is configured to move the magnetic sensor arrangement relative to the axially magnetized magnet in a direction different to the first magnetic field angle or the second magnetic field angle and different to the first magnetic field angle ±180° or different to the second magnetic field angle ±180°.

Aspect 11: The magnet-based positioning system according to Aspect 5, further comprising: a third magnetic sensor element located at a third yet unknown position, wherein the magnetic sensor arrangement is configured to: determine a third magnetic field vector at the third yet unknown position in the x-y-plane, and determine a third magnetic field angle that describes an angle of the third magnetic field vector extending between the third yet unknown position and the common z-axis.

Aspect 12: The magnet-based positioning system according to Aspect 11, wherein, if the magnetic sensor arrangement determines that the first magnetic field angle and the second magnetic field angle are identical, or are shifted by ±180°, the magnetic sensor arrangement is configured to: use the third magnetic field angle instead of the second magnetic field angle, use the third magnetic field vector instead of the second magnetic field vector, and determine the actual x-y-position of the magnetic sensor arrangement relative to the axially magnetized magnet based on the first magnetic field vector and the third magnetic field vector.

Aspect 13: The magnet-based positioning system according to any of Aspects 1-12, wherein the axially magnetized magnet comprises a symmetrical cylinder shape.

Aspect 14: A method for performing a magnet-based position determination, the method comprising: providing an axially magnetized magnet having two opposing magnetic poles arranged along a common z-axis; providing a magnetic sensor arrangement being axially spaced apart from the axially magnetized magnet, and being configured to determine magnetic field vectors in an x-y-plane perpendicular to the common z-axis, the magnetic field vectors representing directions of emanated magnetic field lines in the x-y-plane; determining a first magnetic field vector at a first yet unknown position in the x-y-plane; determining a second magnetic field vector at a different second yet unknown position in the x-y-plane; and determining an actual x-y-position of the magnetic sensor arrangement relative to the axially magnetized magnet based on the first magnetic field vector and the second magnetic field vector and based on a known relative spatial distance between the first yet unknown position and the second yet unknown position.

Aspect 15: The method according to Aspect 14, wherein determining the actual x-y-position of the magnetic sensor arrangement relative to the axially magnetized magnet is based on a triangulation using the first magnetic field vector and the second magnetic field vector.

Aspect 16: The method according to any of Aspects 14-15, further comprising: determining a first magnetic field angle that describes an angle of the first magnetic field vector extending between the first yet unknown position and the common z-axis; and determining a second magnetic field angle that describes an angle of the second magnetic field vector extending between the second yet unknown position and the common z-axis.

Aspect 17: The method according to Aspect 16, wherein the known relative spatial distance between the first yet unknown position and the second yet unknown position is known, and wherein the method further comprises: determining the actual x-y-position of the magnet sensor arrangement relative to the axially magnetized magnet by calculating a spatial distance between at least one of the first yet unknown position or the second yet unknown position and the common z-axis based on the first magnetic field angle and the second magnetic field angle and based on the known relative spatial distance between the first yet unknown position and the second yet unknown position.

Aspect 18: The method according to Aspect 17, wherein the magnetic sensor arrangement comprises a first magnetic sensor element located at the first yet unknown position and a second magnetic sensor element located at the second yet unknown position, and wherein a spatial distance between the first magnetic sensor element and the second magnetic sensor element defines the known relative spatial distance between the first yet unknown position and the second yet unknown position.

Aspect 19: The method according to Aspect 17, wherein the magnetic sensor arrangement comprises a single magnetic sensor element, wherein the method further comprises: moving the single magnetic sensor element from the first yet unknown position to the second yet unknown position along a predetermined moving distance, wherein the predetermined moving distance defines the known relative spatial distance between the first yet unknown position and the second yet unknown position; determining the first magnetic field angle when the single magnetic sensor element is located at the first yet unknown position; and determining the second magnetic field angle when the single magnetic sensor element is located at the second yet unknown position.

Aspect 20: The method according to Aspect 19, wherein moving the single magnetic sensor element from the first yet unknown position to the second yet unknown position along the predetermined moving distance comprises: moving the single magnetic sensor element in a direction different to the first magnetic field angle and different to the first magnetic field angle ±180°.

Aspect 21: The method according to Aspect 19, wherein moving the single magnetic sensor element from the first yet unknown position to the second yet unknown position along the predetermined moving distance comprises: moving the single magnetic sensor element in a direction perpendicular to the first magnetic field angle.

Aspect 22: The method according to Aspect 16, wherein, based on determining that the first magnetic field angle and the second magnetic field angle are identical, or are shifted by ±180°, the method further comprises: moving the magnetic sensor arrangement relative to the axially magnetized magnet and determining the second magnetic field angle at a third yet unknown position.

Aspect 23: The method according to Aspect 22, wherein moving the magnetic sensor arrangement relative to the axially magnetized magnet comprises: moving the magnetic sensor arrangement relative to the axially magnetized magnet in a direction different to the first magnetic field angle or the second magnetic field angle and different to the first magnetic field angle ±180° or different to the second magnetic field angle ±180°.

Aspect 24: The method according to Aspect 18, wherein the magnetic sensor arrangement comprises a third magnetic sensor element located at a third yet unknown position, wherein the method further comprises: determining a third magnetic field vector at the third yet unknown position in the x-y-plane; and determining a third magnetic field angle that describes an angle of the third magnetic field vector extending between the third yet unknown position and the common z-axis.

Aspect 25: The method according to Aspect 24, wherein, based on determining that the first magnetic field angle and the second magnetic field angle are identical, or are shifted by ±180°, the method further comprises: using the third magnetic field angle instead of the second magnetic field angle; using the third magnetic field vector instead of the second magnetic field vector; and determining the actual x-y-position of the magnetic sensor arrangement relative to the axially magnetized magnet based on the first magnetic field vector and the third magnetic field vector.

Aspect 26: A non-transitory computer-readable storage medium having a computer

program, stored thereon, for causing a computer or a signal processor to execute a method for performing a magnet-based position determination using an axially magnetized magnet having two opposing magnetic poles arranged along a common z-axis, and using a magnetic sensor arrangement being axially spaced apart from the axially magnetized magnet, and being configured to determine magnetic field vectors in an x-y-plane perpendicular to the common z-axis, the magnetic field vectors representing directions of emanated magnetic field lines in the x-y-plane, the method comprising: determining a first magnetic field vector at a first yet unknown position in the x-y-plane; determining a second magnetic field vector at a different second yet unknown position in the x-y-plane; and determining an actual x-y-position of the magnetic sensor arrangement relative to the axially magnetized magnet based on the first magnetic field vector and the second magnetic field vector and based on a known relative spatial distance between the first yet unknown position and the second yet unknown position.

1. A magnet-based positioning system, comprising:
an axially magnetized magnet,
wherein two opposing magnetic poles of the axially magnetized magnet are arranged along a common z-axis; and
a magnetic sensor arrangement being axially spaced apart from the axially magnetized magnet, and being configured to determine magnetic field vectors in an x-y-plane perpendicular to the common z-axis, the magnetic field vectors representing directions of emanated magnetic field lines in the x-y-plane,
wherein the magnetic sensor arrangement is configured to determine a first magnetic field vector at a first yet unknown position in the x-y-plane, and to determine a second magnetic field vector at a different second yet unknown position in the x-y-plane, and to determine an actual x-y-position of the magnetic sensor arrangement relative to the axially magnetized magnet based on the first magnetic field vector and the second magnetic field vector and based on a known relative spatial distance between the first yet unknown position and the second yet unknown position.

2. The magnet-based positioning system according to claim 1, wherein the magnetic sensor arrangement is configured to determine the actual x-y-position based on a triangulation using the first magnetic field vector and the second magnetic field vector.

3. The magnet-based positioning system according to claim 1, wherein the magnetic sensor arrangement is configured to:
determine a first magnetic field angle that describes an angle of the first magnetic field vector extending between the first yet unknown position and the common z-axis, and
determine a second magnetic field angle that describes an angle of the second magnetic field vector extending between the second yet unknown position and the common z-axis.

4. The magnet-based positioning system according to claim 3,
wherein the known relative spatial distance between the first yet unknown position and the second yet unknown position is known to the magnetic sensor arrangement, and
wherein the magnetic sensor arrangement is configured to determine the actual x-y-position relative to the axially magnetized magnet by calculating a spatial distance between at least one of the first yet unknown position or the second yet unknown position and the common z-axis based on the first magnetic field angle and the second magnetic field angle and based on the known relative spatial distance between the first yet unknown position and the second yet unknown position.

5. The magnet-based positioning system according to claim 4,
wherein the magnetic sensor arrangement comprises a first magnetic sensor element located at the first yet unknown position and a second magnetic sensor element located at the second yet unknown position, and
wherein a spatial distance between the first magnetic sensor element and the second magnetic sensor element defines the known relative spatial distance between the first yet unknown position and the second yet unknown position.

6. The magnet-based positioning system according to claim 4,
wherein the magnetic sensor arrangement comprises a single magnetic sensor element,
wherein the magnet-based positioning system is configured to move the single magnetic sensor element from the first yet unknown position to the second yet unknown position along a predetermined moving distance,
wherein the predetermined moving distance defines the known relative spatial distance between the first yet unknown position and the second yet unknown position, and
wherein the magnetic sensor arrangement is configured to:
determine the first magnetic field angle when the single magnetic sensor element is located at the first yet unknown position, and
determine the second magnetic field angle when the single magnetic sensor element is located at the second yet unknown position.

7. The magnet-based positioning system according to claim 6, wherein, after determining the first magnetic field angle, the magnet-based positioning system is configured to move the single magnetic sensor element in a direction different to the first magnetic field angle and different to the first magnetic field angle ±180°.

8. The magnet-based positioning system according to claim 6, wherein, after determining the first magnetic field angle, the magnet-based positioning system is configured to move the single magnetic sensor element in a direction perpendicular to the first magnetic field angle.

9. The magnet-based positioning system according to claim 3, wherein, if the magnetic sensor arrangement determines that the first magnetic field angle and the second magnetic field angle are identical, or are shifted by ±180°, the magnet-based positioning system is configured to move the magnetic sensor arrangement relative to the axially magnetized magnet and to determine the second magnetic field angle at a third yet unknown position.

10. The magnet-based positioning system according to claim 9, the magnet-based positioning system is configured to move the magnetic sensor arrangement relative to the axially magnetized magnet in a direction different to the first magnetic field angle or the second magnetic field angle and different to the first magnetic field angle ±180° or different to the second magnetic field angle ±180°.

11. The magnet-based positioning system according to claim 5, further comprising:
a third magnetic sensor element located at a third yet unknown position,
wherein the magnetic sensor arrangement is configured to:
determine a third magnetic field vector at the third yet unknown position in the x-y-plane, and
determine a third magnetic field angle that describes an angle of the third magnetic field vector extending between the third yet unknown position and the common z-axis.

12. The magnet-based positioning system according to claim 11, wherein, if the magnetic sensor arrangement determines that the first magnetic field angle and the second magnetic field angle are identical, or are shifted by ±180°, the magnetic sensor arrangement is configured to:
use the third magnetic field angle instead of the second magnetic field angle,
use the third magnetic field vector instead of the second magnetic field vector, and
determine the actual x-y-position of the magnetic sensor arrangement relative to the axially magnetized magnet based on the first magnetic field vector and the third magnetic field vectors.

13. The magnet-based positioning system according to claim 1, wherein the axially magnetized magnet comprises a symmetrical cylinder shape.

14. A method for performing a magnet-based position determination, the method comprising:
providing an axially magnetized magnet having two opposing magnetic poles arranged along a common z-axis;
providing a magnetic sensor arrangement being axially spaced apart from the axially magnetized magnet, and being configured to determine magnetic field vectors in an x-y-plane perpendicular to the common z-axis, the magnetic field vectors representing directions of emanated magnetic field lines in the x-y-plane;
determining a first magnetic field vector at a first yet unknown position in the x-y-plane;
determining a second magnetic field vector at a different second yet unknown position in the x-y-plane; and
determining an actual x-y-position of the magnetic sensor arrangement relative to the axially magnetized magnet based on the first magnetic field vector and the second magnetic field vector and based on a known relative spatial distance between the first yet unknown position and the second yet unknown position.

15. The method according to claim 14, wherein determining the actual x-y-position of the magnetic sensor arrangement relative to the axially magnetized magnet is based on a triangulation using the first magnetic field vector and the second magnetic field vector.

16. The method according to claim 14, further comprising:
determining a first magnetic field angle that describes an angle of the first magnetic field vector extending between the first yet unknown position and the common z-axis; and
determining a second magnetic field angle that describes an angle of the second magnetic field vector extending between the second yet unknown position and the common z-axis.

17. The method according to claim 16,
wherein the known relative spatial distance between the first yet unknown position and the second yet unknown position is known, and
wherein the method further comprises;
determining the actual x-y-position of the magnet sensor arrangement relative to the axially magnetized magnet by calculating a spatial distance between at least one of the first yet unknown position or the second yet unknown position positions and the common z-axis based on the first magnetic field angle and the second magnetic field angle and based on the known relative spatial distance between the first yet unknown position and the second yet unknown position.

18. The method according to claim 17,
wherein the magnetic sensor arrangement comprises a first magnetic sensor element located at the first yet unknown position and a second magnetic sensor element located at the second yet unknown position, and
wherein a spatial distance between the first magnetic sensor element and the second magnetic sensor element defines the known relative spatial distance between the first yet unknown position and the second yet unknown position.

19. The method according to claim 17,
wherein the magnetic sensor arrangement comprises a single magnetic sensor element,
wherein the method further comprises:
moving the single magnetic sensor element from the first yet unknown position to the second yet unknown position along a predetermined moving distance,
wherein the predetermined moving distance defines the known relative spatial distance between the first yet unknown position and the second yet unknown position;
determining the first magnetic field angle when the single magnetic sensor element is located at the first yet unknown position; and
determining the second magnetic field angle when the single magnetic sensor element is located at the second yet unknown position.

20. The method according to claim 19, wherein moving the single magnetic sensor element from the first yet unknown position to the second yet unknown position along the predetermined moving distance comprises:
moving the single magnetic sensor element in a direction different to the first magnetic field angle and different to the first magnetic field angle ±180°.

21. The method according to claim 19, wherein moving the single magnetic sensor element from the first yet unknown position to the second yet unknown position along the predetermined moving distance comprises:
moving the single magnetic sensor element in a direction perpendicular to the first magnetic field angle.

22. The method according to claim 16, wherein, based on determining that the first magnetic field angle and the second magnetic field angle are identical, or are shifted by ±180°, the method further comprises:
moving the magnetic sensor arrangement relative to the axially magnetized magnet and determining the second magnetic field angle at a third yet unknown position.

23. The method according to claim 22, wherein moving the magnetic sensor arrangement relative to the axially magnetized magnet comprises:
moving the magnetic sensor arrangement relative to the axially magnetized magnet in a direction different to the first magnetic field angle or the second magnetic field angle and different to the first magnetic field angle ±180° or different to the second magnetic field angle ±180°.

24. The method according to 18, wherein the magnetic sensor arrangement comprises a third magnetic sensor element located at a third yet unknown position,
wherein the method further comprises:
determining a third magnetic field vector at the third yet unknown position in the x-y-plane; and
determining a third magnetic field angle that describes an angle of the third magnetic field vector extending between the third yet unknown position and the common z-axis.

25. The method according to claim 24, wherein, based on determining that the first magnetic field angle and the second magnetic field angle are identical, or are shifted by ±180°, the method further comprises:
using the third magnetic field angle instead of the second magnetic field angle;
using the third magnetic field vector instead of the second magnetic field vector; and
determining the actual x-y-position of the magnetic sensor arrangement relative to the axially magnetized magnet based on the first magnetic field vector and the third magnetic field vector.

26. A non-transitory computer-readable storage medium having a computer program, stored thereon, for causing a computer or a signal processor to execute a method for performing a magnet-based position determination using an axially magnetized magnet having two opposing magnetic poles arranged along a common z-axis, and using a magnetic sensor arrangement being axially spaced apart from the axially magnetized magnet, and being configured to determine magnetic field vectors in an x-y-plane perpendicular to the common z-axis, the magnetic field vectors representing directions of emanated magnetic field lines in the x-y-plane, the method comprising:
determining a first magnetic field vector at a first yet unknown position in the x-y-plane;
determining a second magnetic field vector at a different second yet unknown position in the x-y-plane; and
determining an actual x-y-position of the magnetic sensor arrangement relative to the axially magnetized magnet based on the first magnetic field vector and the second magnetic field vector and based on a known relative spatial distance between the first yet unknown position and the second yet unknown position.
